(19) United States
(12) Patent Application Publication
(10) Pub. No.: US 2010/0326520 A1
(43) Pub. Date: Dec. 30, 2010

(54) THIN FILM SOLAR CELL AND MANUFACTURING METHOD THEREOF

(75) Inventor: Chin-Yao Tsai, Tainan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: AURIA SOLAR CO., LTD., Tainan (TW)

(21) Appl. No.: 12/824,255

(22) Filed: Jun. 28, 2010

(30) Foreign Application Priority Data
Jun. 29, 2009 (TW) 98121863
Jul. 24, 2009 (TW) 98125096

(51) Int. Cl. H01L 31/0368; H01L 31/00; H01L 31/0256; H01L 31/18

(52) U.S. Cl. 136/258; 136/252; 136/261; 136/260; 438/97; 438/98; 257/E31.043; 257/E31.124

(57) ABSTRACT

A thin film solar cell including a substrate, a first conductive layer, a first photovoltaic layer, a second conductive layer and a crystallization layer is provided. The first conductive layer is disposed on the substrate. The first photovoltaic layer is disposed on the first conductive layer. The second conductive layer is disposed on the first photovoltaic layer. The crystallization layer is at least partially disposed between the first photovoltaic layer and the first conductive layer or between the first photovoltaic layer and the second conductive layer. A manufacturing method of the thin film solar cell is also provided.

This application claims the priority benefits of Taiwan patent application serial no. 98121863, filed on Jun. 29, 2009, and application serial no. 98125096, filed on Jul. 24, 2009. The entirety of each of the above-mentioned patent applications is hereby incorporated by reference herein and made a part of specification.

### BACKGROUND OF THE INVENTION

1. Field of Invention

The present invention relates to a solar cell and a manufacturing method thereof, and more generally to a thin film solar cell and a manufacturing method thereof.

2. Description of Related Art

FIG. 1A schematically illustrates a local cross-sectional view of a conventional thin film solar cell. Referring to FIG. 1A, the solar cell 100a mainly includes a substrate 110a, a first conductive layer 120a, a photovoltaic layer 130a and a second conductive layer 150a. The photovoltaic layer 130a at least has a P-type semiconductor layer 132a, an intrinsic layer 136a and a N-type semiconductor layer 134a.

Generally speaking, when the thin film solar cell 100a includes a stacked structure, the photovoltaic layer 130a thereof is usually formed by two materials having different energy gaps, such as amorphous silicon and polycrystalline silicon. For example, as compared with the case of the photovoltaic layer 130a of polycrystalline silicon, more dangling bonds are present on the contact surface 131a or 133a between the photovoltaic layer 130a of amorphous silicon and the conductive layer 120a or 150a. Accordingly, the surface recombination of electron-hole pairs easily occurs near the contact surface 131a or 133a between the photovoltaic layer 130a and the conductive layer 120a or 150a, and the photoelectric conversion efficiency of the thin film solar cell 100a is affected.

FIG. 1B schematically illustrates a structure of a tandem thin film solar cell. Referring to FIG. 1B, the solar cell 100b mainly includes a substrate 110b, a first conductive layer 120b, a first photovoltaic layer 130b, a second photovoltaic layer 140b and a second conductive layer 150b. The first photovoltaic layer 130b includes a P-type semiconductor layer 132b, a N-type semiconductor layer 134b and an intrinsic layer 136b. The second photovoltaic layer 140b includes a P-type semiconductor layer 142b, a N-type semiconductor layer 144b and an intrinsic layer 146b. In details, the tandem thin film solar cell 100b includes two photovoltaic layers having different energy gaps.

When sunshine enters the thin film solar cell 100b from the outside of the substrate 110b (e.g. the side near the P-type semiconductor layer 132b), free electron-hole pairs are generated by solar energy in the intrinsic layer 136b between the N-type semiconductor layer 134b and the P-type semiconductor layer 132b, and the internal electric field formed by the N-type semiconductor layer 134b and the P-type semiconductor layer 132b makes electrons and holes respectively move toward two layers. Similarly, free electron-hole pairs are generated by solar energy in the intrinsic layer 146b between the N-type semiconductor layer 144b and the P-type semiconductor layer 142b, and the internal electric field formed by the N-type semiconductor layer 144b and the P-type semiconductor layer 142b makes electrons and holes respectively move toward two layers, so as to generate a storage state of electricity.

However, the P-type semiconductor layer 142b of the second photovoltaic layer 140b is usually formed on the N-type semiconductor layer 134b of the first photovoltaic layer 130b at high temperature in a long period of time. Therefore, different dopant concentration in the P-type semiconductor layer 142b and the N-type semiconductor layer 134b generate an inter-diffusion effect at the interface between the P-type semiconductor layer 142b and the N-type semiconductor layer 134b. Hence, the problem of non-uniform dopant concentration occurs at the interface between the P-type semiconductor layer 142b and the N-type semiconductor layer 134b, and the photoelectric conversion efficiency is accordingly reduced.

### SUMMARY OF THE INVENTION

The present invention provides a thin film solar cell having a crystallization layer between film layers. Accordingly, the dangling bonds on the contact surface between film layers are reduced, so as to further improve the photoelectric characteristics of the thin film solar cell.

The present invention further provides a manufacturing method of a thin film solar cell, in which a crystallization layer is formed between film layers to achieve the advantages of the above-mentioned thin film solar cell.

The present invention also provides a thin film solar cell, in which an interlayer is disposed between stacks of different photovoltaic layers, so as to effectively improve the inter-diffusion effect between the photoelectric layers.

The present invention further provides a manufacturing method to form the above-mentioned thin film solar cell.

The present invention provides a thin film solar cell including a substrate, a first conductive layer, a first photovoltaic layer, a second conductive layer and a crystallization layer. The first conductive layer is disposed on the substrate. The first photovoltaic layer is disposed on the first conductive layer. The second conductive layer is disposed on the first photovoltaic layer. The crystallization layer is at least partially disposed between the first photovoltaic layer and the first conductive layer or between the first photovoltaic layer and the second conductive layer.

The present invention further provides a manufacturing method of a thin film solar cell. A substrate is provided. A first conductive layer is formed on the substrate. A first photovoltaic layer is formed on the first conductive layer. A second conductive layer is formed on the first photovoltaic layer. A crystallization layer is formed between the first photovoltaic layer and the first conductive layer or between the first photovoltaic layer and the second conductive layer, or between the first photovoltaic layer and the first conductive layer and between the first photovoltaic layer and the second conductive layer.

The present invention also provides a thin film solar cell including a substrate, a first electrode layer, a first photovoltaic layer, a second photovoltaic layer, an interlayer and a second electrode layer. The first electrode layer is disposed on the substrate. The first photovoltaic layer is disposed on the first electrode layer. The second photovoltaic layer is disposed on the first photovoltaic layer. The interlayer is disposed between the first photovoltaic layer and the second photovoltaic layer, so as to reduce the inter-diffusion effect generated between the first photovoltaic layer and the second photovoltaic layer. The second electrode layer is disposed on the second photovoltaic layer.

The present invention further provides a manufacturing method of a thin film solar cell. A substrate is provided. A first electrode layer is formed on the substrate. A first photovoltaic layer is formed on the first electrode layer. A second photovoltaic layer is formed on the first photovoltaic layer. An interlayer is formed between the first photovoltaic layer and the second photovoltaic layer, wherein the material of the interlayer is an intrinsic semiconductor or a metal oxide semiconductor. A second electrode layer is formed on the second photovoltaic layer.

In view of the above, in the thin film solar cell of the present invention, the crystallization layer is formed between the photovoltaic layer and the conductive layer or between the adjacent photovoltaic layers, so that the dangling bonds on the contact surface between film layers are reduced, and the photoelectric characteristic (e.g. photoelectric conversion efficiency) of the thin film solar cell is further improved. In addition, the thin film solar cell of the present invention has the interlayer disposed between different photovoltaic layers. The interlayer serves as a buffer layer between the photovoltaic layers, so as to reduce the inter-diffusion effect between the photovoltaic layers, thereby improving the photoelectric conversion efficiency. The material of the interlayer is an intrinsic semiconductor or a metal oxide semiconductor. Besides, the present invention also provides a manufacturing method to form the above-mentioned thin films solar cell.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A schematically illustrates a local cross-sectional view of a conventional thin film solar cell.

FIG. 1B schematically illustrates a structure of a tandem thin film solar cell.

FIG. 2 schematically illustrates a local cross-sectional view of a thin film solar cell according to an embodiment of the present invention.

FIG. 3 schematically illustrates film layers of the first and second photovoltaic layers in FIG. 2.

FIGS. 4A to 4D schematically illustrate a process flow of manufacturing a thin film solar cell according to an embodiment of the present invention.

FIG. 5 schematically illustrates a cross-sectional view of a thin film solar cell according to another embodiment of the present invention.

FIG. 6 schematically illustrates a structure of a thin film solar cell according to yet another embodiment of the present invention.

FIG. 7 schematically illustrates a structure of a thin film solar cell according to still another embodiment of the present invention.

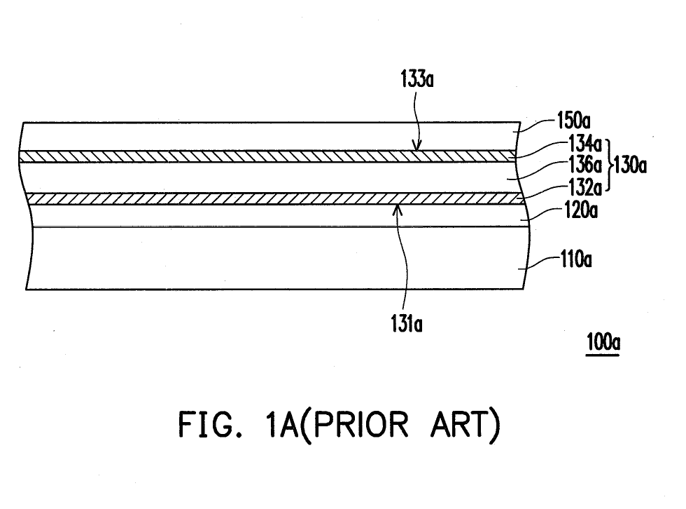

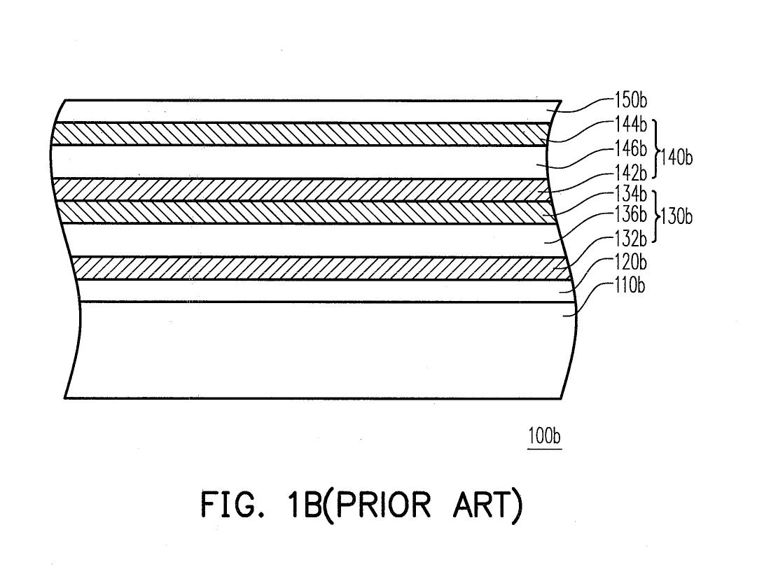

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

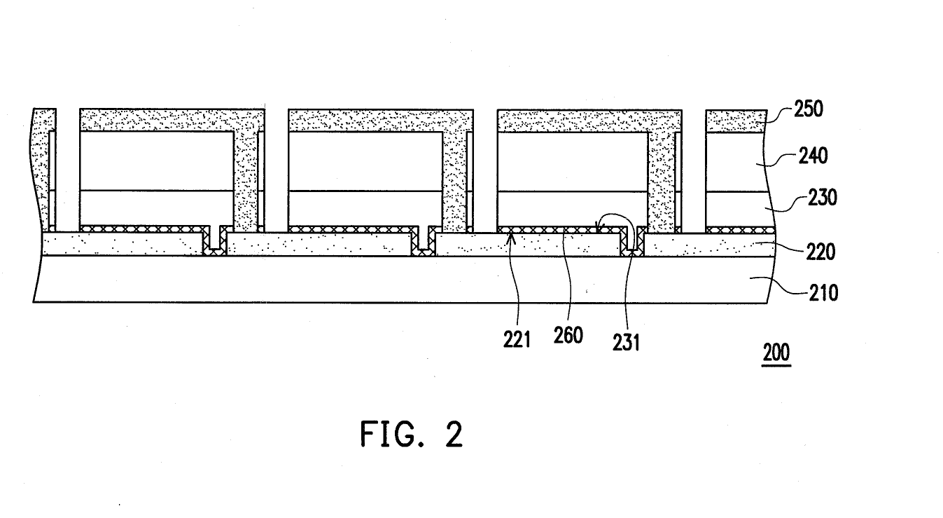

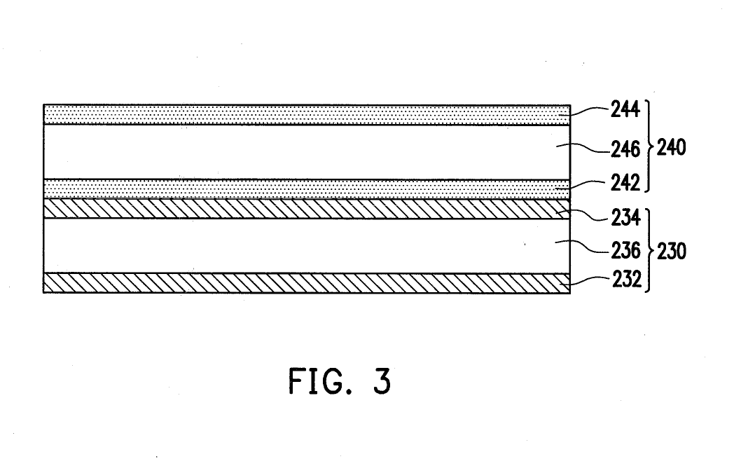

FIG. 2 schematically illustrates a local cross-sectional view of a thin film solar cell according to an embodiment of the present invention. FIG. 3 schematically illustrates film layers of the first and second photovoltaic layers in FIG. 2. Referring to FIG. 2 and FIG. 3, the thin film solar cell 200 of this embodiment includes a substrate 210, a first conductive layer 220, a first photovoltaic layer 230, a second photovoltaic layer 240, a second conductive layer 250 and a crystallization layer 260. The first conductive layer 220 is disposed on the substrate 210. In this embodiment, the substrate can be a transparent substrate, such as a glass substrate. The first conductive layer 220 can be a transparent conductive layer, and the material thereof can be at least one of indium tin oxide (ITO), indium zinc oxide (IZO), indium tin zinc oxide (ITZO), zinc oxide, aluminium tin oxide (ATO), aluminium zinc oxide (AZO), cadmium indium oxide (CIO), cadmium zinc oxide (CZO), gallium zinc oxide (GZO) and fluorine tin oxide (FTO).

In another embodiment (not shown), the first conductive layer 220 can be a stacked layer of a reflective layer (not shown) and the above-mentioned transparent conductive layer, and the reflective layer is disposed between the transparent conductive layer and the substrate 210. The material of the reflective layer can be a metal with higher reflectivity, such as silver (Ag) or aluminium (Al).

The first photovoltaic layer 230 is disposed on the first conductive layer 220, as shown in FIG. 2. In this embodiment, the first photovoltaic layer 230 includes a P-type semiconductor layer 232 and a N-type semiconductor layer 234 (as shown in FIG. 3), and the P-type semiconductor layer 232 can be disposed at the side near the first conductive layer 220. In another embodiment (not shown), the N-type semiconductor layer 234 can be disposed at the side near the first conductive layer 220.

In this embodiment, the doped material of the P-type semiconductor layer 232 can be selected from the group consisting of elements of Group III in the Periodic Table, such as boron (B), aluminium (Al), gallium (Ga), indium (In) and thallium (Tl). The doped material of the N-type semiconductor layer 234 can be selected from the group consisting of elements of Group V in the Periodic Table, such as nitrogen (N), phosphorous (P), arsenic (As), antimony (Sb) and bismuth (Bi).

In addition, the first photovoltaic layer 230 further includes an intrinsic layer 236 disposed between the P-type semiconductor layer 232 and the N-type semiconductor layer 234. In details, the intrinsic layer 236 can be an undoped intrinsic semiconductor layer or a slightly doped intrinsic semiconductor layer. Therefore, the first photovoltaic layer 230 can be a PIN photovoltaic structure. In another embodiment, the first photovoltaic layer 230 can be a PN photovoltaic structure without the intrinsic layer 236.

It is noted that in this embodiment, the materials of the P-type semiconductor layer 232, the N-type semiconductor layer 234 and the intrinsic layer 236 of the first photovoltaic layer 230 are amorphous silicon (a-Si), for example. That is, the first photovoltaic layer 230 of this embodiment is illustrated with the film layer structure of an amorphous silicon thin film solar cell. However, the present invention is not limited thereto. In other embodiments, the material of the first photovoltaic layer 230 can be a Group IV thin film, a III-V compound semiconductor thin film, a II-VI compound semiconductor thin film or an organic compound semiconductor thin film.

In details, the Group IV thin film includes at least one of amorphous silicon (a-Si), microcrystalline silicon (μc-Si), amorphous silicon germanium (a-SiGe), microcrystalline silicon germanium (μc-SiGe), amorphous silicon carbide (a-SiC) and microcrystalline silicon carbide (μc-SiC). The III-V compound semiconductor thin film includes at least one of gallium arsenide (GaAs) and indium gallium phosphide (InGaP). The II-VI compound semiconductor thin film includes at least one of copper indium diselenide (CIS), copper indium gallium diselenide (CIGS) and cadmium telluride (CdTe). The organic compound semiconductor thin film includes a mixture of a small molecular organic compound, a conjugated polymer and PCBM.

That is, the first photovoltaic layer 230 can at least include the film layer structure of an amorphous silicon thin film solar cell, a microcrystalline silicon thin film solar cell, a tandem thin film solar cell, a triple thin film solar cell, a CIS thin film solar cell, a CIGS thin film solar cell, a GdTe thin film solar cell or an organic thin film solar cell. In other words, the first photovoltaic layer 230 of this embodiment is provided only for illustration purposes, and can be decided according to the users' requirements. The first photovoltaic layer 230 can also include the film layer structure of another suitable thin film solar cell.

Referring to FIG. 2, the second photovoltaic layer 240 is disposed on the first photovoltaic layer 230. In this embodiment, the second photovoltaic layer 240 includes a P-type semiconductor layer 242 and a N-type semiconductor layer 244 (as shown in FIG. 3), and the P-type semiconductor layer 242 can be disposed at the side near the first photovoltaic layer 230. In another embodiment (not shown), the N-type semiconductor layer 244 can be disposed at the side near the first photovoltaic layer 230.

Similarly, in this embodiment, the doped material of the P-type semiconductor layer 242 can be selected from the group consisting of elements of Group III in the Periodic Table, such as boron (B), aluminium (Al), gallium (Ga), indium (In) and thallium (Tl). The doped material of the N-type semiconductor layer 244 can be selected from the group consisting of elements of Group V in the Periodic Table, such as nitrogen (N), phosphorous (P), arsenic (As), antimony (Sb) and bismuth (Bi).

In addition, the second photovoltaic layer 240 further includes an intrinsic layer 246 disposed between the P-type semiconductor layer 242 and the N-type semiconductor layer 244. In details, the intrinsic layer 246 can be an undoped intrinsic semiconductor layer or a slightly doped intrinsic semiconductor layer. Similarly, the second photovoltaic layer 240 can be a PIN photovoltaic structure. In another embodiment, the second photovoltaic layer 240 can be a PN photovoltaic structure without the intrinsic layer 246.

It is noted that in this embodiment, the materials of the P-type semiconductor layer 242, the N-type semiconductor layer 244 and the intrinsic layer 246 of the second photovoltaic layer 240 are polycrystalline silicon (poly-Si) or microcrystalline silicon (μc-Si), for example. That is, the second photovoltaic layer 240 of this embodiment is illustrated with the film layer structure of an amorphous silicon thin film solar cell. However, the present invention is not limited thereto. In other embodiments, the material of the second photovoltaic layer 240 can be a Group IV thin film, a III-V compound semiconductor thin film, a II-VI compound semiconductor thin film or an organic compound semiconductor thin film. The Group IV thin film includes at least one of amorphous silicon (a-Si), microcrystalline silicon (μc-Si), amorphous silicon germanium (a-SiGe), microcrystalline silicon germanium (μc-SiGe), amorphous silicon carbide (a-SiC) and microcrystalline silicon carbide (μc-SiC). The III-V compound semiconductor thin film includes at least one of gallium arsenide (GaAs) and indium gallium phosphide (InGaP). The II-VI compound semiconductor thin film includes at least one of copper indium diselenide (CIS), copper indium gallium diselenide (CIGS) and cadmium telluride (CdTe). The organic compound semiconductor thin film includes a mixture of a conjugated polymer and PCBM.

In this embodiment, the first photovoltaic layer 230 includes amorphous silicon, and the second photovoltaic layer 240 includes polycrystalline silicon or microcrystalline silicon. The amorphous silicon material and the polycrystalline silicon or microcrystalline silicon material have different energy gaps and accordingly different absorption spectrums. Therefore, in this embodiment, the tandem structure of amorphous silicon and microcrystalline silicon can enhance the light absorption rate of the thin film solar cell 200. However, the materials of the first photovoltaic layer 230 and the second photovoltaic layer 240 are not limited by the present invention. The photovoltaic layers stacked with different materials and/or formed through different crystallization methods can extend the range of wavelengths absorbed by the thin film solar cell 200, so that solar energy is sufficiently utilized and higher photoelectric conversion efficiency is achieved. It is for sure that the thin film solar cell 200 can include the film layer structure of a III-V solar cell, a II-VI solar cell or an organic thin film solar cell.

In addition, the second conductive layer 250 is disposed on the second photovoltaic layer 240. In this embodiment, the second conductive layer 250 can include the material of the above-mentioned transparent conductive layer, and the details are not iterated herein. In this embodiment, the second conductive layer 250 can further include a reflective layer disposed on the transparent conductive layer. It is noted that when the second conductive layer 250 includes a reflective layer, the first conductive layer 220 can only be a transparent conductive layer. On the contrary, when the first conductive layer 220 includes a reflective layer, the second conductive layer 250 can only be a transparent conductive layer without a reflective layer thereon. In an embodiment, each of the first conductive layer 220 and the second conductive layer 250 can be a single transparent conductive layer without a reflective layer thereon. In other words, the design of the first conductive layer 220 and the second conductive layer 250 can be adjusted by the users' requirements (e.g. for manufacturing a thin film solar cell with double-sided illumination or a thin film solar cell with one-sided illumination). The design of the first conductive layer 220 and the second conductive layer 250 described above is provided only for illustration purposes, and is not construed as limiting the present invention.

The crystallization layer 260 is at least partially disposed between the first photovoltaic layer 230 and the first conductive layer 220 or between the second photovoltaic layer 240 and the second conductive layer 250, as shown in FIG. 2. In this embodiment, the crystallization layer 260 can be a film layer formed by crystallizing the surface 231 of the first photovoltaic layer 230 near the first conductive layer 220, or formed by crystallizing the surface 221 of the first conductive layer 220 near the first photovoltaic layer 230. In details, when the material of the first photovoltaic layer 230 is amorphous silicon, a plurality of dangling bonds are present on the contact surfaces 231 and 221 between the first photovoltaic layer 230 and the first conductive layer 220. Therefore, the surface recombination of electron-hole pairs easily occurs near the contact surfaces 231 and 221 between the first photovoltaic layer 230 and the first conductive layer 220, so as to affect the photoelectric conversion efficiency of the thin film solar cell 200. In this embodiment, the dangling bonds are reduced on the contact surfaces by crystallizing the surface 231 of the first photovoltaic layer 230 or by crystallizing the surface 221 of the first conductive layer 220, so that the photoelectric characteristics (e.g. photoelectric conversion efficiency) of the thin film solar cell 200 is improved.

In addition, the crystallization layer 260 can also be disposed between the second photovoltaic layer 240 and the second conductive layer 250. The reason has been described above. Accordingly, the above-mentioned advantages can be achieved, and the details are not iterated herein. In an embodiment, the crystallization layer 260 can also be at least partially disposed between the first photovoltaic layer 230 and the second photovoltaic layer 240 so as to achieve the above-mentioned advantages.

Moreover, since the crystallization layer 260 is a film layer formed by crystallizing the surface of the photovoltaic layer 230 or 240 or the conductive layer 220 or 250, the material thereof can be a semiconductor (e.g. silicon or germanium), a metal of a metal oxide.

In view of the above, the thin film solar cell 200 has the crystallization layer 260 disposed between the first conductive layer 220 and the first photovoltaic layer 230 or between the second conductive layer 250 or the second photovoltaic layer 240, so that the dangling bonds on the contact surface between film layers are reduced. Accordingly, the electrical performance of the thin film solar cell 200 is improved, and the higher photoelectric conversion efficiency is further achieved.

It is noted that the thin film solar cell 200 further includes an intrinsic material layer (not shown) disposed between the first photovoltaic layer 230 and the second photovoltaic layer 240. The intrinsic material layer can reduce the carrier inter-diffusion problem due to direct contact between the first photovoltaic layer 230 and the second photovoltaic layer 240, so as to improve the photoelectric characteristics.

In addition, the present invention also provides a manufacturing method to form the above-mentioned thin film solar cell 200, which is described in the following.

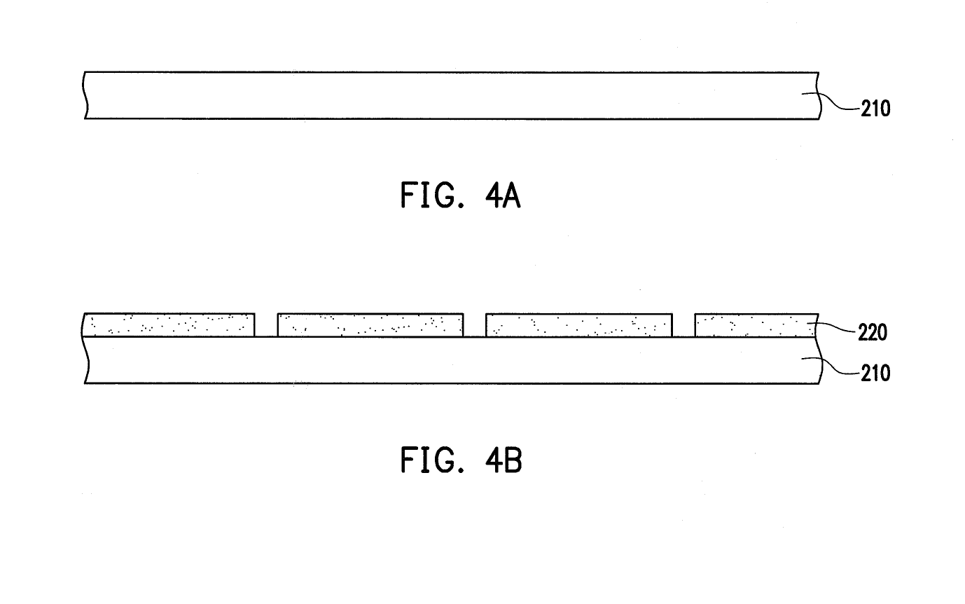

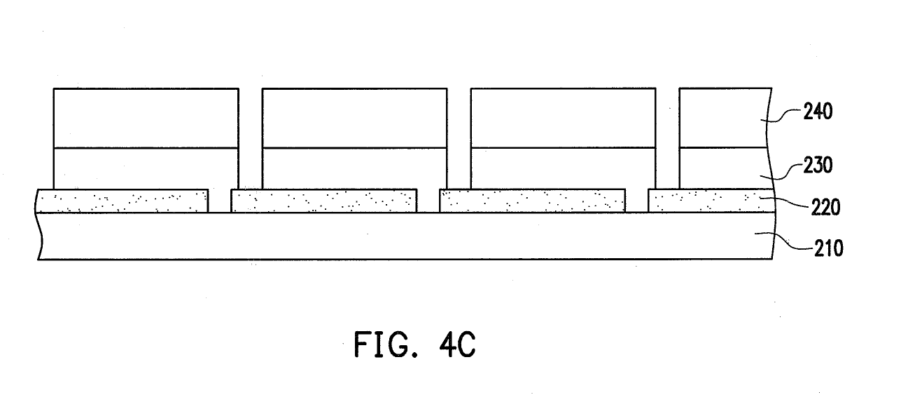

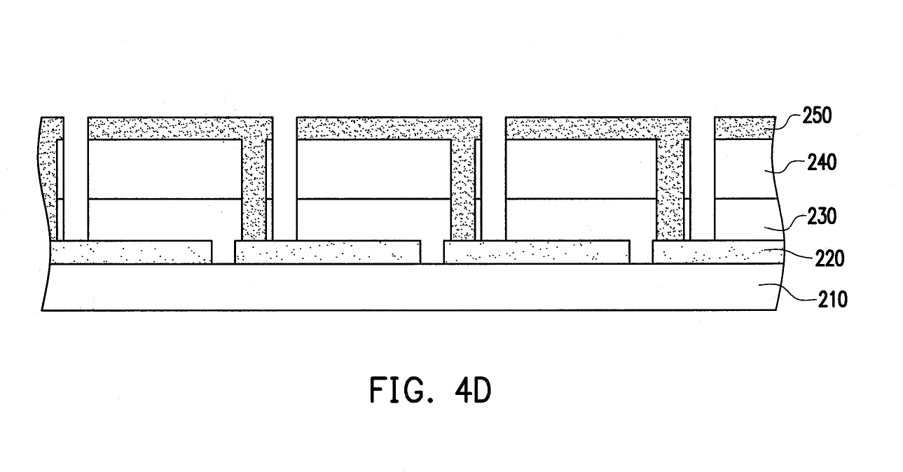

FIGS. 4A to 4D schematically illustrate a process flow of manufacturing a thin film solar cell according to an embodiment of the present invention. Referring to FIG. 4A, the above-mentioned substrate 210 is provided. The substrate 210 has been described above, and the details are not iterated herein.

Thereafter, the above-mentioned first conductive layer 220 is formed on the substrate 210, as shown in FIG. 4B. In this embodiment, the method of forming the first conductive layer 220 is by performing a sputtering process, a metal organic chemical vapour deposition (MOCVD) process or an evaporation process, for example. Generally speaking, in the manufacturing process of the thin film solar cell 200, after the first conductive layer 220 is formed, a first laser process is performed to pattern the first conductive layer 220, so as to form bottom electrodes of a plurality of sub cells connected in series. The laser or patterning process is well known to persons skilled in the art, and the details are not iterated herein.

Afterwards, the first photovoltaic layer 230 and the second photovoltaic layer 240 described above are sequentially formed on the first conductive layer 220, as shown in FIG. 4C. In this embodiment, the method of forming the first photovoltaic layer 230 or the second photovoltaic layer 240 is by performing a radio frequency plasma enhanced chemical vapour deposition (RF PECVD) process, a vary high frequency plasma enhanced chemical vapour deposition (VHF PECVD) process or a microwave plasma enhanced chemical vapour deposition (MW PECVD) process, for example. Accordingly, the first photovoltaic layer 230 and the second photovoltaic layer 240 are blanket-formed on the substrate 210. The above-mentioned forming method of the first photovoltaic layer 230 or the second photovoltaic layer 240 is provided only for illustration purposes, and is not construed as limiting the present invention. The forming method of the first photovoltaic layer 230 or the second photovoltaic layer 240 can be adjusted depending on the required film layer design (e.g. the structure of the above-mentioned Group IV thin film or II-VI compound semiconductor thin film). Similarly, after the first photovoltaic layer 230 and the second photovoltaic layer 240 are formed, a second laser process is performed to simultaneously pattern the first photovoltaic layer 230 and the second photovoltaic layer 240, so as to form the first photovoltaic layer 230 and the second photovoltaic layer 240 as shown in FIG. 4C. The laser or patterning process is well known to persons skilled in the art, and the details are not iterated herein.

Further, the above-mentioned second conductive layer 250 is formed on the second photovoltaic layer 240, as shown in FIG. 4D. In this embodiment, the second conductive layer 250 and the first conductive layer 220 have the same forming method, and the details are not iterated herein. Similarly, after the second conductive layer 250 is formed, a third laser process is performed to pattern the second conductive layer 250, so as to form top electrodes of the plurality of sub cells connected in series. The laser or patterning process is well known to persons skilled in the art, and the details are not iterated herein.

Next, the above-mentioned crystallization layer 260 is formed between the first photovoltaic layer 230 and the first conductive layer 220 or between the second photovoltaic layer 240 and the second conductive layer 250, or between the first photovoltaic layer 230 and the first conductive layer 220 and between the second photovoltaic layer 240 and the second conductive layer 250, as shown in FIG. 2. In FIG. 2, the crystallization layer 260 is only formed between the first photovoltaic layer 230 and the first conductive layer 220. In this embodiment, the method of forming the crystallization layer 260 is by performing a surface treatment process to the surface of the first conductive layer 220, the first photovoltaic layer 230, the second photovoltaic layer 240 or the second conductive layer 250, for example. In details, the surface treatment process can be an annealing process, a laser process, a metal induced crystallization process or a rapid thermal process, and can be decided according to the surface of the film layer 220, 230, 240 or 250 to be crystallized. It is noted that the step of crystallizing the surface of the film layer 220, 230, 240 or 250 is not limited to be implemented after the steps in FIG. 4D are completed. That is, the step of crystallizing the surface of the film layer 220, 230, 240 or 250 can be implemented during the step of forming the film layer 220, 230, 240 or 250. The thin film solar cell 200 is thus completed.

It is noted that the thin film solar cell 200 and the manufacturing method thereof are illustrated with a tandem thin film solar cell. However, the present invention is not limited thereto. In another embodiment, the thin film solar cell 200 can further include a third photovoltaic layer (not shown) disposed between the second photovoltaic layer 240 and the second conductive layer 250, so as to form a triple junction thin film solar cell. In this embodiment, the third photovoltaic layer can include the material of the first photovoltaic layer 230 or the second photovoltaic layer 240, the forming method thereof has been described above, and the details are not iterated herein. It is noted that the crystallization layer 260 can also be at least partially disposed between the second photovoltaic layer 240 and the third photovoltaic layer or between the third photovoltaic layer and the second conductive layer 250.

In addition, the thin film solar cell 200 can further include an interface layer (not shown) disposed between the second photovoltaic layer 240 and the third photovoltaic layer. The interface layer can be a transparent conductive layer or an intrinsic layer, and the forming method thereof can be a chemical deposition process, a sputtering process or another suitable method.

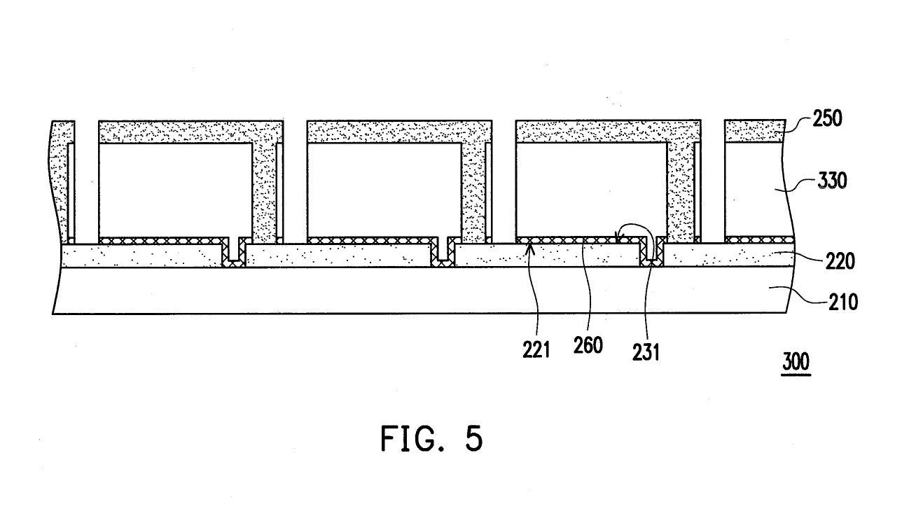

In an embodiment of the present invention, another thin film solar cell 300 as shown in FIG. 5 is provided. FIG. 5 schematically illustrates a cross-sectional view of a thin film solar cell according to another embodiment of the present invention. The thin film solar cells 300 and 200 have a similar structure, and the difference between them lies in that the thin film solar cell 300 only includes the film layer structure of the first photovoltaic layer 230. That is, the photovoltaic layer 330 of the thin film solar cell 300 is designed as a single layer rather than the above-mentioned tandem type.

In this embodiment, the thin film solar cell 300 has the above-mentioned crystallization layer 260. The crystallization layer 260 is disposed between the photovoltaic layer 330 and the first conductive layer 220 or between the photovoltaic layer 330 and the second conductive layer 250, so as to reduce the dangling bond present between the photovoltaic layer 330 and the conductive layer 220 or 250. In other words, the thin film solar cell 300 also has the above-mentioned advantages, and the details are not iterated herein.

Since the step of depositing the second photovoltaic layer 240 is omitted when the thin film solar cell 300 is formed, the manufacturing steps of the thin film solar cell 300 are simpler than that of the thin film solar cell 200. In addition, persons skilled in the art can refer to the process flow of manufacturing the thin film solar cell 200 to infer the manufacturing method of the thin film solar cell 300, so that the details are not iterated herein.

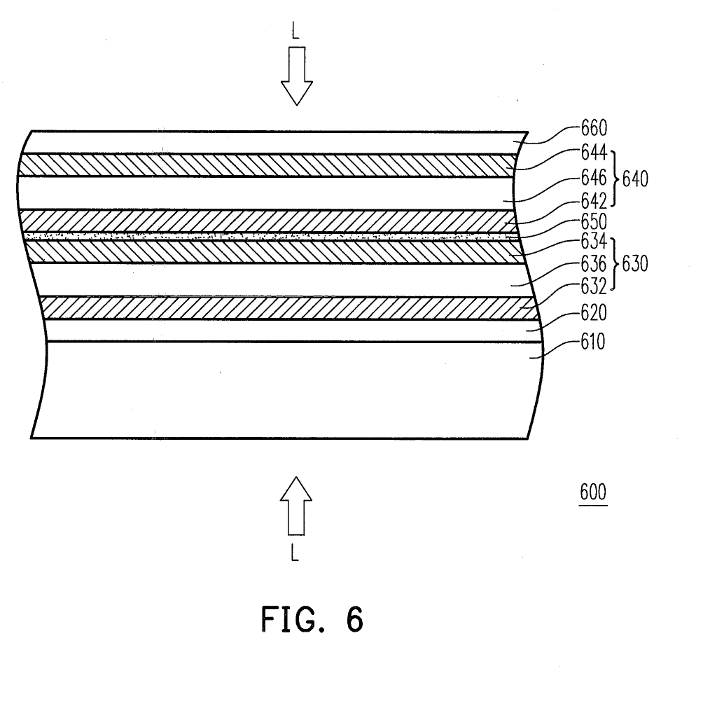

FIG. 6 schematically illustrates a structure of a thin film solar cell according to yet another embodiment of the present invention. Referring to FIG. 6, the thin film solar cell 600 of this embodiment includes a substrate 610, a first electrode layer 620, a first photovoltaic layer 630, a second photovoltaic layer 640, an interlayer 650 and a second electrode layer 660.

The first electrode layer 620 is disposed on the substrate 610. In this embodiment, the substrate 610 is a transparent substrate, such as a glass substrate or a transparent resin substrate. The first electrode layer 620 includes the material of the above-mentioned first conductive layer 220.

In another embodiment, the first electrode layer 620 can be a stacked layer (not shown) of a reflective layer and a transparent conductive layer, and the reflective layer is disposed between the transparent conductive layer and the substrate 610. The material of the reflective layer can be a metal with higher reflectivity, such as aluminium (Al), silver (Ag) or molybdenum (Mo).

The first photovoltaic layer 630 is disposed on the first electrode layer 620. In this embodiment, the first photovoltaic layer 630 includes a first-type semiconductor layer 632 and a second-type semiconductor layer 634. The first-type semiconductor layer 632 is disposed at the side near the first electrode layer 620. In addition, in this embodiment, the first-type semiconductor layer 632 is a P-type semiconductor layer and the second-type semiconductor layer 634 is a N-type semiconductor layer. In another embodiment, the first-type semiconductor layer 632 can be a N-type semiconductor layer and the second-type semiconductor layer 634 can be a P-type semiconductor layer.

In this embodiment, the first photovoltaic layer 630 further includes an intrinsic layer 636 disposed between the first-type semiconductor layer 632 and the second-type semiconductor layer 634. The material of the intrinsic layer 636 can be an undoped intrinsic semiconductor or a slightly doped semiconductor. Accordingly, a PIN semiconductor stacked structure is formed. In another embodiment, the first photovoltaic layer 630 can be a PN semiconductor stacked structure without the intrinsic layer 636.

In this embodiment, the first photovoltaic layer 630 can be the above-mentioned Group IV thin film, III-V compound semiconductor thin film, II-VI compound semiconductor thin film or organic compound semiconductor thin film, and the details are not iterated herein. This embodiment in which the first-type semiconductor layer 632, the second-type semiconductor layer 634 and the intrinsic layer 636 of the first photovoltaic layer 630 include amorphous silicon is provided for illustration purposes, and is not construed as limiting the present invention.

The second photovoltaic layer 640 is disposed on the first photovoltaic layer 630, as shown in FIG. 6. In this embodiment, the second photovoltaic layer 640 includes a first-type semiconductor layer 642 and a second-type semiconductor layer 644. The first-type semiconductor layer 642 is disposed at the side near the first photovoltaic layer 630. In addition, in this embodiment, the first-type semiconductor layer 642 is a P-type semiconductor layer and the second-type semiconductor layer 644 is a N-type semiconductor layer. Similarly, in another embodiment, the first-type semiconductor layer 642 can be a N-type semiconductor layer and the second-type semiconductor layer 644 can be a P-type semiconductor layer.

In this embodiment, the second photovoltaic layer 640 further includes an intrinsic layer 646 disposed between the first-type semiconductor layer 642 and the second-type semiconductor layer 644. The material of the intrinsic layer 646 can be an undoped intrinsic semiconductor or a slightly doped semiconductor. Accordingly, a PIN semiconductor stacked structure is formed. In another embodiment, the second photovoltaic layer 640 can be a PN semiconductor stacked structure without the intrinsic layer 646.

Similarly, the second photovoltaic layer 640 can be the above-mentioned Group IV thin film, III-V compound semiconductor thin film, II-VI compound semiconductor thin film or organic compound semiconductor thin film, and the details are not iterated herein. This embodiment in which the first-type semiconductor layer 642, the second-type semiconductor layer 644 and the intrinsic layer 646 of the second photovoltaic layer 640 include microcrystalline silicon is provided for illustration purposes, and is not construed as limiting the present invention.

In this embodiment, the first photovoltaic layer 630 includes amorphous silicon, and the second photovoltaic layer 640 includes microcrystalline silicon. The amorphous silicon material and the microcrystalline silicon material have different energy gaps and accordingly different absorption spectrums. Therefore, in this embodiment, the tandem structure of amorphous silicon and microcrystalline silicon can enhance the light absorption rate of the thin film solar cell 600. However, the materials of the first photovoltaic layer 630 and the second photovoltaic layer 640 are not limited by the present invention. The photovoltaic layers stacked with different materials and/or formed through different crystallization methods can extend the range of wavelengths absorbed by the thin film solar cell 600, so that solar energy is sufficiently utilized and higher photoelectric conversion efficiency is achieved. It is for sure that the thin film solar cell 600 can include the film layer structure of a CIS thin film solar cell, a CIGS thin film solar cell, a GdTe thin film solar cell or an organic thin film solar cell.

It is noted that electrons and holes at the interface between the first photovoltaic layer 630 and the second photovoltaic layer 640 may shift to each other upon the effect of the process temperature and time, so that the inter-diffusion effect is generated at the interface, and the manufacturing yield and photoelectric conversion efficiency of thin film solar cell are affected. In this embodiment, the interlayer 650 is disposed between the first photovoltaic layer 630 and the second photovoltaic layer 640, so as to reduce the inter-diffusion effect generated between the first photovoltaic layer 630 and the second photovoltaic layer 640. It is noted that the material of the interlayer 650 is an intrinsic semiconductor or a metal oxide semiconductor. In details, the intrinsic semiconductor can be amorphous silicon, microcrystalline silicon, monocrystalline silicon, polycrystalline silicon or a combination thereof. The metal oxide semiconductor can be at least one of indium tin oxide (ITO), indium zinc oxide (IZO), indium tin zinc oxide (ITZO), zinc oxide, aluminium tin oxide (ATO), aluminium zinc oxide (AZO), cadmium indium oxide (CIO), cadmium zinc oxide (CZO), gallium zinc oxide (GZO) and fluorine tin oxide (FTO).

In addition, the second electrode layer 660 is disposed on the second photovoltaic layer 640. In this embodiment, the second electrode layer 660 includes at least one of a reflective layer and a transparent conductive layer. Similarly, the material of the transparent conductive layer can be at least one of indium tin oxide (ITO), indium zinc oxide (IZO), indium tin zinc oxide (ITZO), zinc oxide, aluminium tin oxide (ATO), aluminium zinc oxide (AZO), cadmium indium oxide (CIO), cadmium zinc oxide (CZO), gallium zinc oxide (GZO) and fluorine tin oxide (FTO). The material of the reflective layer is a metal with higher reflectivity, such as silver (Ag) or aluminium (Al).

In another embodiment, the second electrode layer 660 can be a transparent conductive layer. Similarly, the material of the transparent conductive layer can be at least one of indium tin oxide (ITO), indium zinc oxide (IZO), indium tin zinc oxide (ITZO), zinc oxide, aluminium tin oxide (ATO), aluminium zinc oxide (AZO), cadmium indium oxide (CIO), cadmium zinc oxide (CZO), gallium zinc oxide (GZO) and fluorine tin oxide (FTO).

It is noted that when one of the first electrode layer 620 and the second electrode layer 660 includes a reflective layer, the thin film solar cell 600 can only receive the light L from one side. That is, when the second electrode layer 660 includes a reflective layer (not shown), the light L enters one side of the first electrode layer 620, sequentially passes the first electrode layer 620, the first photovoltaic layer 630, the interlayer 650 and the second photovoltaic layer 640, and is reflected back by the reflection layer of the second electrode layer 660. Accordingly, the light L is utilized again to further improve the photoelectric conversion efficiency of the thin film solar cell 600.

In addition, the present invention also provides a manufacturing method of the above-mentioned thin film solar cell 600, which is described in the following. First, the above-mentioned substrate 610 is provided. Thereafter, the above-mentioned first electrode layer 620 is formed on the substrate 610. In this embodiment, the method of forming the first electrode layer 620 is by performing a sputtering process, a metal organic chemical vapour deposition (MOCVD) process or an evaporation process, for example. Generally speaking, in the manufacturing process of the thin film solar cell 600, after the first electrode layer 620 is formed, a first laser process is performed to pattern the first electrode layer 620, so as to form bottom electrodes of a plurality of sub cells connected in series. The laser or patterning process is well known to persons skilled in the art, and the details are not iterated herein.

Afterwards, the above-mentioned first photovoltaic layer 630 is formed on the first electrode layer 620. In this embodiment, the method of forming the first photovoltaic layer 630 is by performing a radio frequency plasma enhanced chemical vapour deposition (RF PECVD) process, a vary high frequency plasma enhanced chemical vapour deposition (VHF PECVD) process or a microwave plasma enhanced chemical vapour deposition (MW PECVD) process, for example. The forming method of the first photovoltaic layer 630 is provided only for illustration purposes, and can be adjusted according to the film layer design of the first photovoltaic layer 630.

Further, the above-mentioned interlayer 650 is formed on the first photovoltaic layer 630. The material of the interlayer 650 is an intrinsic semiconductor or a metal oxide semiconductor. In this embodiment, the method of forming the interlayer 650 is by performing a radio frequency plasma enhanced chemical vapour deposition (RF PECVD) process, a vary high frequency plasma enhanced chemical vapour deposition (VHF PECVD) process or a microwave plasma enhanced chemical vapour deposition (MW PECVD) process, for example.

Next, the above-mentioned second photovoltaic layer 640 is formed on the interlayer 650. In this embodiment, the second photovoltaic layer 640 and the first photovoltaic layer 630 have the same forming method, and the details are not iterated herein. Similarly, after the first photovoltaic layer 630, the interlayer 650 and the second photovoltaic layer 640 are formed, a second laser process is performed to simultaneously pattern the first photovoltaic layer 630, the interlayer 650 and the second photovoltaic layer 640. The laser or patterning process is well known to persons skilled in the art, and the details are not iterated herein.

Thereafter, the above-mentioned second electrode layer 660 is formed on the second photovoltaic layer 640, as shown in FIG. 6. In this embodiment, the second electrode layer 660 can be formed by adopting the method of forming the first electrode layer 620, and the details are not iterated herein. Similarly, after the second electrode layer 660 is formed, a third laser process is performed to pattern the second electrode layer 660, so as to form top electrodes of the plurality of sub cells connected in series. The laser or patterning process is well known to persons skilled in the art, and the details are not iterated herein. The thin film solar cell 600 as shown in FIG. 6 is thus completed.

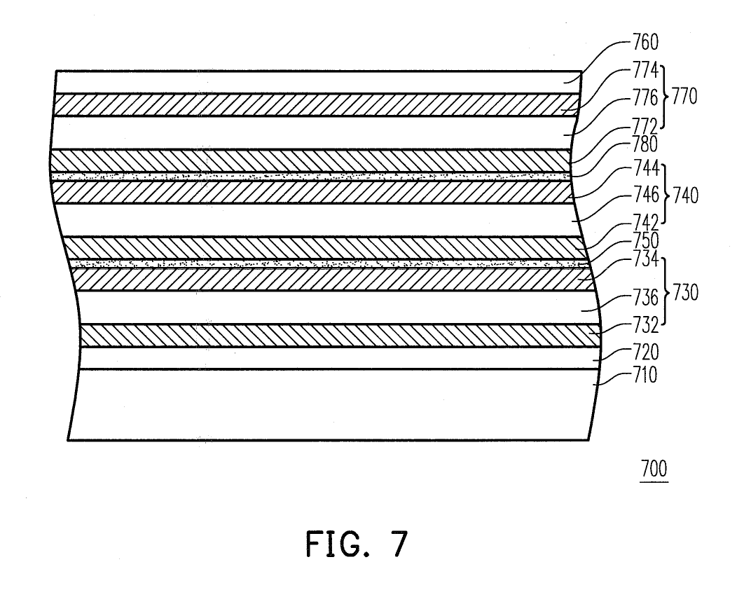

FIG. 7 schematically illustrates a structure of a thin film solar cell according to still another embodiment of the present invention. Referring to FIG. 7, the thin film solar cell 700 and the thin film solar cell 600 have a similar structure, and the difference between them lies in that the thin film solar cell 700 further includes a third photovoltaic layer 770 disposed between the second photovoltaic layer 740 and the second electrode layer 760.

In this embodiment, the third photovoltaic layer 770 of the thin film solar cell 700 includes a first-type semiconductor layer 772, a second-type semiconductor layer 774 and an intrinsic layer 776. The property of the third photovoltaic layer 770 is similar to that of the first photovoltaic layer 630 or the second photovoltaic layer 640 of the above-mentioned embodiment, and the details are not iterated herein.

It is noted that in this embodiment, the first-type semiconductor layer 772, the second-type semiconductor layer 774 and the intrinsic layer 776 of the third photovoltaic layer 770 include polycrystalline silicon. Accordingly, a triple tandem structure of amorphous silicon, microcrystalline silicon and polycrystalline silicon is formed to further enhance the light absorption rate of the thin film solar cell 700.

However, the materials of the first photovoltaic layer 730, the second photovoltaic layer 740 and the third photovoltaic layer 770 are not limited by the present invention. In another embodiment, the material of the third photovoltaic layer 770 can be a Group IV thin film, a compound semiconductor thin film, a II-VI compound semiconductor thin film or an organic compound semiconductor thin film. In details, the Group IV thin film includes at least one of amorphous silicon (a-Si), microcrystalline silicon (μc-Si), amorphous silicon germanium (a-SiGe), microcrystalline silicon germanium (μc-SiGe), amorphous silicon carbide (a-SiC) and microcrystalline silicon carbide (μc-SiC). The III-V compound semiconductor thin film includes at least one of gallium arsenide (GaAs) and indium gallium phosphide (InGaP). The II-VI compound semiconductor thin film includes at least one of copper indium diselenide (CIS), copper indium gallium diselenide (CIGS) and cadmium telluride (CdTe). The organic compound semiconductor thin film includes a mixture of poly(3-hexylthiophene) (P3HT) and PCBM, for example. In other words, the photovoltaic layers stacked with different materials and/or formed through different crystallization methods can extend the range of wavelengths absorbed by the thin film solar cell 700, so that solar energy is sufficiently utilized and higher photoelectric conversion efficiency is achieved.

Similarly, the thin film solar cell 700 has an interlayer 750 disposed between the first photovoltaic layer 730 and the second photovoltaic layer 740, so as to reduce the inter-diffusion effect generated between the first photovoltaic layer 730 and the second photovoltaic layer 740. The thin film solar cell 700 also has the advantages of the thin film solar cell 200 of the above-mentioned embodiment, and the details are not iterated herein.

In this embodiment, the thin film solar cell 700 further includes a second interlayer 780 disposed between the second photovoltaic layer 740 and the third photovoltaic layer 770. In this embodiment, the second interlayer 780 includes an intrinsic semiconductor, so as to reduce the inter-diffusion effect generated at the interface between the second photovoltaic layer 740 and the third photovoltaic layer 770, thereby enhancing the manufacturing yield and the photoelectric conversion efficiency. In another embodiment, the second interlayer 780 includes a metal oxide semiconductor, so as to enhance the conductivity between the second photovoltaic layer 740 and the third photovoltaic layer 770.

The thin film solar cells 200 and 700 of the above-mentioned embodiments are provided only for illustration purposes. The number and structure of the photovoltaic layers in the thin film solar cell are not limited by the present invention, and can be adjusted by persons skilled in the art upon the requirements.

In this embodiment, a manufacturing method of the above-mentioned thin film solar cell 700 is also provided. The thin film solar cells 700 and 600 have similar manufacturing steps, and the difference between them lies in that the third photovoltaic layer 770 is further formed between the second photovoltaic layer 740 and the second electrode layer 760, as shown in FIG. 7. The third photovoltaic layer 770 can be formed by adopting the method of forming the first photovoltaic layer 730 or the second photovoltaic layer 740, and the details are not iterated herein.

In addition, the manufacturing method of the thin film solar cell 700 further includes forming the second interlayer 780 between the second photovoltaic layer 740 and the third photovoltaic layer 770. The forming method of the second interlayer 780 depends on the material of the same. For example, when the second interlayer 780 includes an intrinsic semiconductor, it can be formed by adopting the method of forming the above-mentioned interlayer 650. When the second interlayer 780 includes a metal oxide semiconductor, it can be formed by adopting the method of forming the above-mentioned first electrode layer 620, and the details are not iterated herein.

In summary, the thin film solar cell of the present invention and the manufacturing method thereof at least have the following advantages. The crystallization layer is at least formed between the photovoltaic layer and the conductive layer or between the adjacent photovoltaic layers, so that the dangling bonds on the contact surface between film layers are reduced. Accordingly, the possibility of the surface recombination of electron-hole pairs on the contact surface between film layers is decreased, and the photoelectric characteristic (e.g. photoelectric conversion efficiency) of the thin film solar cell is further improved. Beside, the present invention also provides a manufacturing method to form the above-mentioned thin film solar cell.

In addition, the thin film solar cell of the present invention has the interlayer between stacks of different photovoltaic layers. The undoped or slightly doped interlayer can reduce the inter-diffusion effect between the stacks, so as to enhance the manufacturing yield and whole photoelectric conversion efficiency of the stacks. Accordingly, the photoelectric conversion efficiency of the thin film solar cell is improved, the production yield is increased and the production cost is reduced. Further, the thin film solar cell formed by the method of the present invention has higher light utilization rate.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A thin film solar cell, comprising:
a substrate;
a first conductive layer, disposed on the substrate;
a first photovoltaic layer, disposed on the first conductive layer;
a second conductive layer, disposed on the first photovoltaic layer; and
a crystallization layer, at least partially disposed between the first photovoltaic layer and the first conductive layer or between the first photovoltaic layer and the second conductive layer.

2. The thin film solar cell of claim 1, further comprising a second photovoltaic layer disposed between the first photovoltaic layer and the second conductive layer, wherein the crystallization layer is at least partially disposed between the second photovoltaic layer and the second conductive layer.

3. The thin film solar cell of claim 2, wherein the crystallization layer is at least partially disposed between the first photovoltaic layer and the second photovoltaic layer.

4. The thin film solar cell of claim 1, wherein a material of the crystallization layer comprises a semiconductor, a metal or a metal oxide.

5. The thin film solar cell of claim 1, wherein the first photovoltaic layer is a PN semiconductor layer or a PIN semiconductor layer.

6. The thin film solar cell of claim 2, wherein each of the first photovoltaic layer and the second photovoltaic layer is a Group IV thin film, a III-V compound semiconductor thin film, a II-VI compound semiconductor thin film, an organic compound semiconductor thin film or a combination thereof.

7. The thin film solar cell of claim 1, wherein at least one of the first conductive layer and the second conductive layer is a transparent conductive layer.

8. A manufacturing method of a thin film solar cell, comprising:
providing a substrate;
forming a first conductive layer on the substrate;
forming a first photovoltaic layer on the first conductive layer;
forming a second conductive layer on the first photovoltaic layer; and
forming a crystallization layer between the first photovoltaic layer and the first conductive layer or between the first photovoltaic layer and the second conductive layer, or between the first photovoltaic layer and the first conductive layer and between the first photovoltaic layer and the second conductive layer.

9. The manufacturing method of claim 8, further comprising forming a second photovoltaic layer between the first photovoltaic layer and the second conductive layer.

10. The manufacturing method of claim 9, further comprising forming the crystallization layer between the first photovoltaic layer and the second photovoltaic layer or between the second photovoltaic layer and the second conductive layer.

11. The manufacturing method of claim 8, wherein a method of forming the crystallization layer comprises a surface treatment process.

12. The manufacturing method of claim 11, wherein the surface treatment process comprises an annealing process, a laser process, a metal induced crystallization process or a rapid thermal process.

13. The manufacturing method of claim 9, further comprising forming an intrinsic material layer between the first photovoltaic layer and the second photovoltaic layer.

14. A thin film solar cell, comprising:
a substrate;
a first electrode layer, disposed on the substrate;
a first photovoltaic layer, disposed on the first electrode layer;
a second photovoltaic layer, disposed on the first photovoltaic layer;
an interlayer, disposed between the first photovoltaic layer and the second photovoltaic layer, so as to reduce an inter-diffusion effect generated between the first photovoltaic layer and the second photovoltaic layer; and
a second electrode layer, disposed on the second photovoltaic layer.

15. The thin film solar cell of claim 14, wherein each of the first photovoltaic layer and the second photovoltaic layer is a Group IV thin film, a III-V compound semiconductor thin film, a II-VI compound semiconductor thin film or an organic compound semiconductor thin film.

16. The thin film solar cell of claim 14, wherein a material of the interlayer is an intrinsic semiconductor or a metal oxide semiconductor.

17. The thin film solar cell of claim 16, wherein the intrinsic semiconductor comprises amorphous silicon, microcrystalline silicon, monocrystalline silicon, polycrystalline silicon or a combination thereof.

18. The thin film solar cell of claim 16, wherein the metal oxide semiconductor comprises at least one of indium tin oxide (ITO), indium zinc oxide (IZO), indium tin zinc oxide (ITZO), zinc oxide, aluminium tin oxide (ATO), aluminium zinc oxide (AZO), cadmium indium oxide (CIO), cadmium zinc oxide (CZO), gallium zinc oxide (GZO) and fluorine tin oxide (FTO).

19. The thin film solar cell of claim 14, wherein each of the first photovoltaic layer and the second photovoltaic layer is a PN semiconductor layer or a PIN semiconductor layer.

20. A manufacturing method of a thin film solar cell, comprising:
providing a substrate;
forming a first electrode layer on the substrate;
forming a first photovoltaic layer on the first electrode layer;
forming a second photovoltaic layer on the first photovoltaic layer;
forming an interlayer between the first photovoltaic layer and the second photovoltaic layer, wherein a material of the interlayer is an intrinsic semiconductor or a metal oxide semiconductor; and
forming a second electrode layer on the second photovoltaic layer.
